(19) United States
(12) Patent Application Publication
(10) Pub. No.: US 2022/0085143 A1
(43) Pub. Date: Mar. 17, 2022

(54) MAGNETIC WIRES AND THEIR APPLICATIONS

(71) Applicant: Intel Corporation, Santa Clara, CA (US)

(72) Inventors: Beomseok CHOI, Chandler, AZ (US); Huong DO, Chandler, AZ (US); Sai VADLAMANI, Gilbert, AZ (US)

(21) Appl. No.: 17/023,249

(22) Filed: Sep. 16, 2020

(51) Int. Cl. H01L 49/02; H01F 27/28; H01F 27/32; H01F 27/245; H01L 23/31

(52) U.S. Cl. CPC H01L 28/10; H01F 27/2866; H01L 23/3157; H01F 27/245; H01F 27/324

(57) ABSTRACT

Embodiments disclosed herein include magnetic structures and methods of forming such structures. In an embodiment, the magnetic structure includes an interconnect. In an embodiment, the interconnect comprises a core, where the core has a thickness and a length between a first end and a second end. In an embodiment, the core is conductive. In an embodiment, the interconnect further comprises a magnetic sheet surrounding the core. In an embodiment, the magnetic sheet comprises is a magnetic layer with a microstructure that comprises grains that are substantially aligned in a single direction.

### TECHNICAL FIELD

Embodiments of the present disclosure relate to semiconductor devices, and more particularly to electronic packages with embedded interconnects with conductive cores surrounded by a magnetic cladding that includes a microstructure with aligned grains.

### BACKGROUND

There are various different types of integrated switched voltage regulators. For example, integrated switched voltage regulators may include fully integrated voltage regulators (FIVR), on-package voltage regulators (VR), switched mode power supplies (SMPS), and power management integrated circuits (PMIC)). Demand for high power integrated switch voltage regulators is increasing. However, the performance of the individual components of the integrated switched voltage regulators has not been able to scale as fast as desired to keep up with the demand. The performance of components (e.g., inductors, transformers, etc.) relies heavily on the magnetic materials. As such, magnetic materials are one bottleneck that challenges the realization of high density and high performance integrated switched VRs.

One solution for providing magnetics within an electronic package is to use a moldable magnetic material that is disposed around conductive features (e.g., vias traces, pads, etc.) to form the component. The performance is thus limited by the material properties of magnetics that are moldable. Moldable magnetic materials are limited because there is no way to induce strain in the magnetic material to align the grains of the microstructure.

Strained magnetic materials with aligned grains have been proposed, but are of limited use to date. This is because strained magnetic materials are usually made into sheets or tapes by the application of physical pressure on the materials. Such configurations limit the use of strained magnetic materials to planar designs or large bulky designs that are not suitable for high performance VR applications where form factor is a significant consideration.

### BRIEF DESCRIPTION OF THE DRAWINGS

FIG. 1A is a roll of a strained magnetic sheet with a microstructure that has grains aligned in a single direction, in accordance with an embodiment.

FIG. 1B is a schematic illustrating a roll-to-roll lamination process that may be used to sandwich a strained magnetic sheet between insulating and/or adhesive layers, in accordance with an embodiment.

FIG. 2A is a cross-sectional illustration of a sheet with a pair of strained magnetic layers, in accordance with an embodiment.

FIG. 2B is a cross-sectional illustration of a sheet with a pair of adjacent strained magnetic layers, in accordance with an embodiment.

FIG. 3A is an illustration of a process for wrapping a strained magnetic sheet around a conductive core to form an interconnect, in accordance with an embodiment.

FIG. 3B is a cross-sectional illustration of the interconnect in FIG. 3A, in accordance with an embodiment.

FIG. 4 is an illustration of a process for rolling a strained magnetic sheet around a conductive core to form an interconnect, in accordance with an embodiment.

FIG. 5 is a cross-sectional illustration of an interconnect with a pair of conductive cores surrounded by a single magnetic sheet, in accordance with an embodiment.

FIG. 6 is an illustration of a bundle of interconnects with strained magnetic sheets connected to a socket, in accordance with an embodiment.

FIG. 7A is an illustration of a pair of interconnects bonded together, in accordance with an embodiment.

FIG. 7B is a cross-sectional illustration of the bonded interconnects embedded in a package substrate to form a planar inductor device, in accordance with an embodiment.

FIG. 8A is an illustration of an inductor module that comprises a plurality of interconnects with strained magnetic sheets, in accordance with an embodiment.

FIG. 8B is a cross-sectional illustration of an electronic package with the inductor module of FIG. 8A embedded in a package core, in accordance with an embodiment.

FIG. 9 is a cross-sectional illustration of an electronic system with an interconnect that comprises a strained magnetic sheet, in accordance with an embodiment.

FIG. 10 is a schematic of a computing device built in accordance with an embodiment.

### EMBODIMENTS OF THE PRESENT DISCLOSURE

Described herein are electronic packages with embedded interconnects with conductive cores surrounded by a magnetic cladding that includes a microstructure with aligned grains, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, the material properties of magnetic materials is currently a limiting factor in the design of high performance inductors and transformers for voltage regulator (VR) architectures. Current designs are largely limited to moldable magnetic materials. Such molded magnetics are not able to be strained. As such, the microstructure of the molded magnetics cannot be properly aligned with the magnetic flux, and the performance is limited.

Accordingly, embodiments disclosed herein include the fabrication of magnetic components that utilize strained magnetic sheets. The strained magnetic sheets include a microstructure with grains that are substantially aligned in a single direction. As such, the magnetic sheets can be properly aligned with the magnetic flux in order to provide high performance components. In an embodiment, the magnetic components (e.g., inductors, transformers, etc.) may be assembled with a tape wrapping process or a sheet rolling process. The resulting components may then be integrated (e.g., embedded) into a package substrate in order to provide the needed on-package magnetics for various VR architectures.

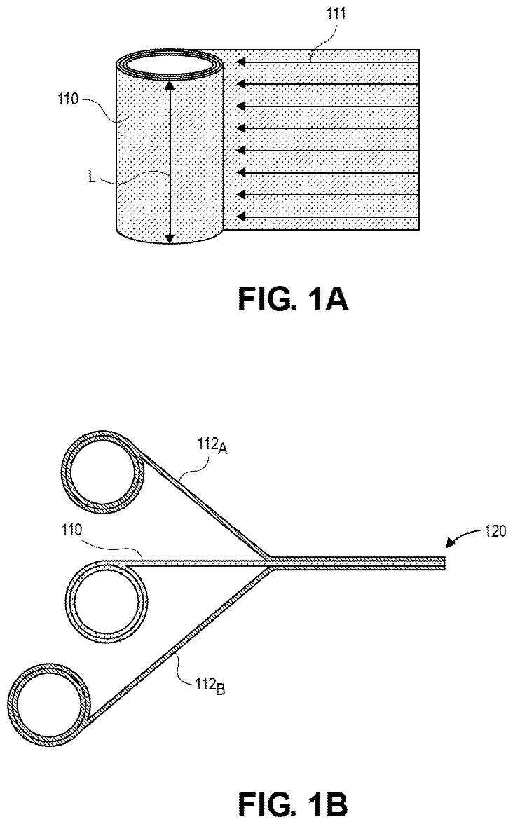

Referring now to FIG. 1A, an illustration of a magnetic layer 110 is shown, in accordance with an embodiment. In an embodiment, the magnetic layer 110 may be provided in a roll. The height L of the roll may be any suitable dimension. In some embodiments, the height L may be smaller than the height of the magnetic components (e.g., to allow for a tape winding process), or the height L may be substantially similar to the height of the magnetic components (e.g., to allow for a sheet rolling process). Tape winding and sheet rolling are described in greater detail below.

In an embodiment, the magnetic layer 110 may be a strained magnetic material. For example, the magnetic layer 110 may be strained with any suitable process, such as cold rolling, pulling, or the like. The straining process alters the microstructure of the magnetic material. Particularly, embodiments include magnetic layer 110 that has a microstructure comprising grains that are substantially aligned in a single direction. For example, arrows 111 in FIG. 1A illustrate the primary grain direction of the magnetic layer 110. As shown, the primary grain direction may be substantially perpendicular to the height direction L of the roll.

In an embodiment, the magnetic layer 110 may be any suitable magnetic material that can be strained. Suitable materials for the magnetic layer 110 include, but are not limited to, compounds of ferrites, iron, aluminum, cobalt, and nickel. In some embodiments, the magnetic layer 110 may be referred to as a high permeability magnetic material. For example, the magnetic permeability of the magnetic layer 110 may be approximately 10μ/μ₀ to or greater.

Referring now to FIG. 1B, an illustration of a roll-to-roll process for forming magnetic sheets 120 is shown in accordance with an embodiment. As shown, the magnetic layer 110 may be fed between a pair of insulating layers 112_{A} and 112_{B}. The resulting magnetic sheet 120 may be rolled back up (not shown) for subsequent use. In an embodiment, the insulating layers 112_{A} and 112_{B} may be any suitable insulative material, such as a polymer or the like. In some embodiments, one or both of the insulating layers 112_{A} and 112_{B} may have adhesive properties in order to aid in the assembly of magnetic components. The insulating layers 112_{A} and 112_{B} may be the same material, or the insulating layer 112_{A} may be different than the insulating layer 112_{B}. While insulating layers 112_{A} and 112_{B} are shown as having substantially the same thickness as the magnetic layer 110, it is to be appreciated that the individual layers of the magnetic sheet 120 may have any suitable thicknesses.

In FIG. 1B, the magnetic sheet 120 is fabricated using a pressing process in order to apply the insulating layers 112_{A} and 112_{B} over opposite surfaces of the magnetic layer 110. However, it is to be appreciated that embodiments are not limited to such a configuration. For example, one or both of the insulating layers 112_{A} and 112_{B} may be applied with a lamination process, a spraying process, or any other material deposition process.

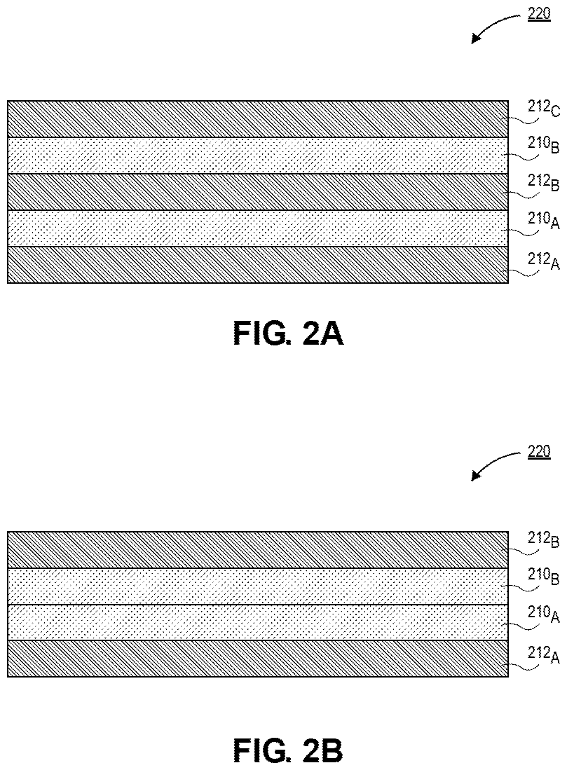

Referring now to FIGS. 2A and 2B, cross-sectional illustrations of magnetic sheets 220 are shown, in accordance with additional embodiments. As shown, the magnetic sheets 220 may comprise material stacks that are different than the material stack shown in FIG. 1B. For example, in FIG. 2A, a pair of magnetic layers 210_{A} and 210_{B} are provided between insulating layers 212_{A}, 212_{B}, and 212_{C}. In an embodiment, the first magnetic layer 210_{A} may be different than the second magnetic layer 210_{B}. In other embodiments, the first magnetic layer 210_{A} may be the same material as the second magnetic layer 210_{B}. While a pair of magnetic layers 210_{A} and 210_{B} are shown, it is to be appreciated that any number of layers of magnetic layers 210 alternating with insulating layers 212 may be used, in accordance with an embodiment.

Referring now to FIG. 2B, a cross-sectional illustration of a magnetic sheet 220 is shown, in accordance with an additional embodiment. In FIG. 2B, a pair of magnetic layers 210_{A} and 210_{B} are adjacent to each other in the magnetic sheet 220. The first magnetic layer 210_{A} may be the same as the second magnetic layer 210_{B}, or they may be different materials. Furthermore, while a stack of two magnetic layers 210_{A} and 210_{B} are shown, it is to be appreciated that any number of magnetic layers 210 may be provided adjacent to each other in the magnetic sheet 220.

FIGS. 2A and 2B provide a pair of examples for the construction of a magnetic sheet 220. However, it is to be appreciated that magnetic sheets 220 described herein may include any number of magnetic material layers 210 and/or any number of insulating layers 212. Additionally, the various layers of the magnetic sheet 220 may be arranged in any desired pattern.

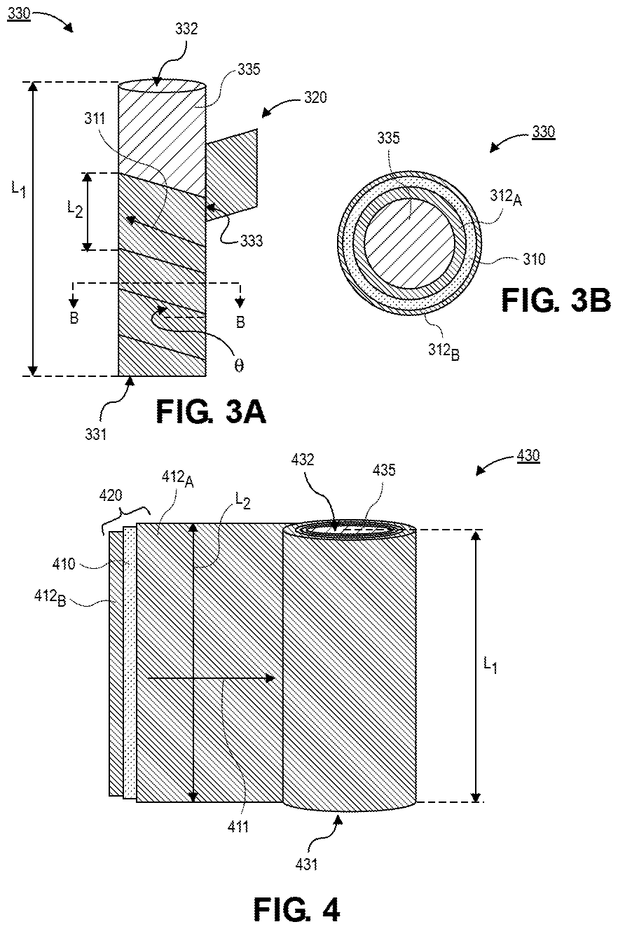

Referring now to FIG. 3A, a perspective view illustration of a process for forming an interconnect 330 is shown, in accordance with an embodiment. As used herein an “interconnect” may refer to a magnetic device or a portion of a magnetic device. For example, the interconnect may be an inductor, a portion of an inductor, a transformer, or a portion of a transformer. Interconnects described herein may include a conductive core (e.g., copper or another conductive material) and a magnetic sheet (e.g., similar to any of the magnetic sheets described above) surrounding the conductive core. In an embodiment, the conductive core may have a circular cross-section or a rectangular cross-section. However, embodiments are not limited to any particular cross-section for the conductive core.

As shown in FIG. 3A, the conductive core 335 has a first length L₁ between a first end surface 331 and a second end surface 332. The first length L₁ may be the desired length of the interconnect 330. However, it is to be appreciated that the first length L₁ may be any desired length. For example, the process illustrated in FIG. 3A may be a continuous process for winding a magnetic sheet 320 along a continuously fed conductive core 335. In a particular embodiment, the magnetic sheet 320 may have a second length L₂. The second length L₂ may be smaller than the desired length of the interconnect 330. Particularly, the second length L₂ may be smaller than the first length L₁. In some embodiments, the magnetic sheet 320 may be referred to as a magnetic tape. In FIG. 3A, the magnetic sheet 320 is shown as a single layer. However, it is to be appreciated that, in some embodiments, the magnetic sheet 320 may be a multi-layer stack that includes one or more magnetic layers and one or more insulating layers.

In an embodiment, the magnetic layer of the magnetic sheet 320 may be a strained magnetic material. The strain may result in the formation of a microstructure with grains that are substantially aligned in a first direction, as indicated by the arrow 311.

In an embodiment, the magnetic sheet 320 is wrapped around the conductive core 335. The magnetic sheet 320 may be wrapped at an angle θ relative to the first surface 331 of the conductive core 335. In an embodiment, the angle θ may be between approximately 0° and approximately 45°. In order to provide complete coverage of the conductive core 335, each winding may have an overlap 333. That is, through some cross-sections of the interconnect 330, there may be more than one layer of the magnetic sheet. 320. In an embodiment, the amount of overlap 333 may be approximately one-half L₂ or less, approximately one-fourth L₂ or less, or approximately one-eighth L₂ or less.

In an embodiment, the direction of the grains in the microstructure of the magnetic material (as indicated by arrow 311) may be transverse to a length direction of the conductive core 335 (i.e., a direction perpendicular to the first surface 331 and the second surface 332). Due to the angled application of the magnetic sheet 320, the alignment of the grains in the microstructure of the magnetic material (as indicated by arrow 311) may be at a non-perpendicular angle to the length direction of the conductive core 335. The non-perpendicular angle may be off from perpendicular by an angle substantially equal to the angle θ.

Referring now to FIG. 3B, a cross-sectional illustration of a portion of the interconnect 330 is shown, in accordance with an embodiment. In an embodiment, the conductive core 335 is surrounded by a single layer of the magnetic sheet 320. However, due to overlapped wrappings, more than a single layer of the magnetic sheet 320 may be present in some cross-sections of the interconnect 330. In an embodiment, the magnetic sheet 320 may comprise a first insulating layer 312_{A} that is in direct contact with the conductive core 335. The first insulating layer 312_{A} may also be an adhesive layer in some embodiments. In an embodiment, the magnetic layer 310 is provided over the first insulating layer 312_{A}. As noted above, the magnetic layer 310 is a strained magnetic material that comprises a microstructure with grains that are substantially aligned in a single direction. In some embodiments, a second insulating layer 312E may be provided over the outer surface of the magnetic layer 310.

The illustrated embodiment depicts a magnetic sheet 320 that is similar to the magnetic sheet 120 in FIG. 1B. However, it is to be appreciated that any stack-up of magnetic materials and insulating layers may be used to form the winding around the conductive core 335, such as the magnetic sheets 220 similar to those shown in FIGS. 2A and 2B.

Referring now to FIG. 4, a perspective view illustration of a rolling process that is used to form an interconnect 430 is shown, in accordance with an embodiment. In a rolling process, a length L₁ of the conductive core 435 between a first surface 431 and a second surface 432 may be substantially equal to a length L₂ of the magnetic sheet 420. The magnetic sheet 420 is then rolled around the conductive core 435 one or more times. The conductive core 435 and magnetic sheet 420 may be singulated to provide a plurality of smaller interconnects 430, or the interconnect 430 may have the length L₁.

In the illustrated embodiment, the magnetic sheet 420 may have a first insulating layer 412A and a second insulating layer 412E that are formed over opposite surfaces of a magnetic layer 410. However, it is to be appreciated that the magnetic sheet 420 may comprise any stack-up structure, such as structures described above with respect to FIGS. 2A and 2B.

In an embodiment, the magnetic layer 410 is a strained magnetic layer. As such, the magnetic layer 410 may have a microstructure that includes grains that are substantially oriented along a single direction, as indicated by arrow 411. In a particular embodiment, the direction of the grain orientation may be transverse to a length direction of the conductive core (i.e., a direction that is orthogonal to the first surface 431 and the second surface 432). In some embodiments, the direction of the grain orientation may be substantially orthogonal to the length direction of the conductive core.

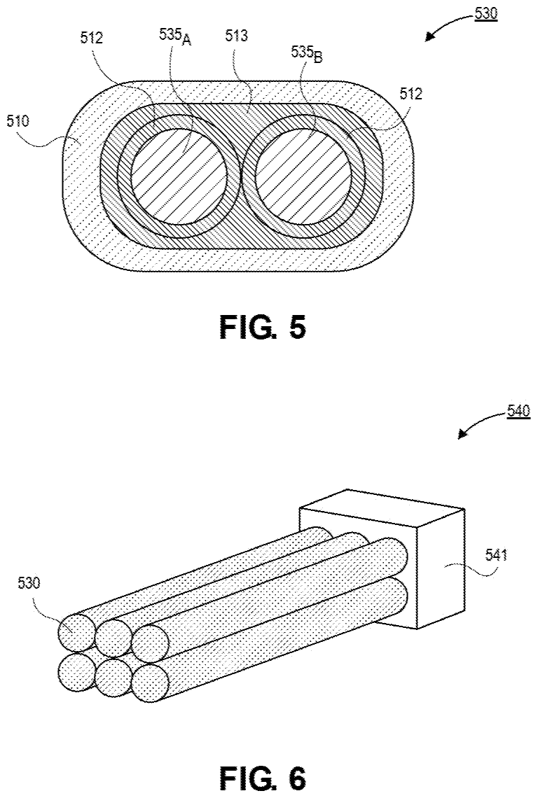

Referring now to FIG. 5, a cross-sectional illustration of an interconnect 530 is shown, in accordance with an additional embodiment. As shown in FIG. 5, a pair of conductive cores 535_{A} and 535_{B} may be surrounded by a single magnetic layer 510. Providing two conductive cores 535_{A} and 535_{B} within a single magnetic layer 510 provides enhanced coupling of the first conductive core 535_{A} and the second conductive core 535_{B}. Such highly coupled features are particularly beneficial for some applications in various VR architectures, such as coupled inductors and/or transformers.

In an embodiment, each of the conductive cores 535_{A} and 535_{B} may be surrounded by a first insulating layer 512. The two insulating layers 512 may be further surrounded by a second insulating layer 513. However, in some embodiments, the second insulating layer 513 may be omitted. A magnetic layer 510 may surround the second insulating layer 513 in some embodiments. The magnetic layer 510 may comprise a strained magnetic material. For example, the magnetic layer 510 may have a microstructure with grains substantially aligned in a single direction. In an embodiment, the grains may be aligned in a direction that is substantially parallel to the plane of the cross-section in FIG. 5.

While shown as having a magnetic layer 510 as the outermost layer, it is to be appreciated that the interconnect 530 may also comprise an additional insulating layer over the outer surface of the magnetic layer 510. Additionally, it is to be appreciated that multiple magnetic layers 510 may surround the conductive cores 535_{A} and 535_{B} (e.g., a single sheet wrapped around the conductive cores 535_{A} and 535_{B} a plurality of times, or a sheet with a plurality of magnetic layers 510 wrapped around the conductive cores 535_{A} and 535_{B} a single time). In an embodiment, the interconnect 530 may be formed with a winding process (e.g., a process similar to the process depicted in FIG. 3A) or a rolling process (e.g., a process similar to the process depicted in FIG. 4).

In FIGS. 1A-5, structures and processes depicting the formation of interconnects are shown. It is to be appreciated that the interconnects described above may be integrated into electronic packages in various architectures. Some examples of how the magnetic interconnects may be integrated into electronic packages are shown in FIGS. 6-8A.

Referring now to FIG. 6, a perspective view illustration of a cable 540 is shown, in accordance with an embodiment. In an embodiment, a plurality of interconnects 530 are coupled to a socket 541. For example six interconnects 530 are coupled to the socket 541. However, it is to be appreciated that any number of interconnects 530 (e.g., one or more) may be connected to a socket 541.

In an embodiment, each of the interconnects 530 in the cable 540 may be a magnetic interconnect. For example, each interconnect 530 may comprise a conductive core that is surrounded by a magnetic sheet. The magnetic sheet may be similar to any of the magnetic sheets described above. For example, the magnetic sheet may comprise a first insulating layer, a magnetic layer, and a second insulating layer. In an embodiment, the magnetic layer is a strained magnetic material. As such, a microstructure of the magnetic material may have grains that are substantially aligned along a single direction. Such cables 540 are particularly beneficial for use as low RFI/EMI emission interconnects. This is because the structure itself is coaxial with the magnetic flux dominantly captured in the surrounding magnetic material.

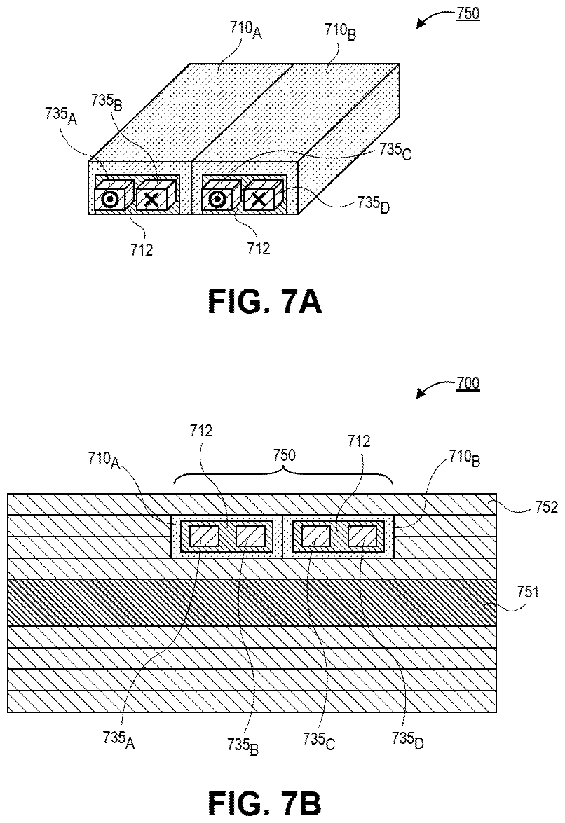

Referring now to FIG. 7A, a perspective view illustration of an interconnect bundle 750 is shown, in accordance with an embodiment. In an embodiment, the bundle 750 may comprise a first magnetic layer 710_{A} and a second magnetic layer 710_{B}. The first magnetic layer 710_{A} may surround a first pair of conductive cores 735_{A} and 735_{B}, and the second magnetic layer 710_{B} may surround a second pair of conductive cores 735_{C} and 735_{B}. In an embodiment, an insulating layer 712 may electrically isolate the cores 735_{A} and 735_{B}, and an insulating layer 712 may electrically isolate the cores 735_{C} and 735_{D}. In an embodiment, the first magnetic layer 710_{A} may be bonded to the second magnetic layer 710_{B}. For example, the magnetic layers 710_{A} and 710_{B} may be bonded together with a pressing and annealing operation. In some embodiments, an additional insulating layer (not shown) may surround the magnetic layers 710_{A} and 710_{B}.

Referring now to FIG. 7B, a cross-sectional illustration of an electronic package 700 is shown, in accordance with an embodiment. The electronic package 700 may comprise a core 751. Buildup layers 752 may be provided above and below the core 751. However, in some embodiments, the core 751 may be omitted to provide a coreless architecture.

In an embodiment, a bundle 750 may be embedded in the electronic package 700. For example, the bundle 750 may be embedded in one or more of the buildup layers 752. In some embodiments, the bundle 750 may optionally be embedded in the core 751. The bundle 750 may function as planar magnetic devices. As used herein, “planar devices” may refer to structures with a conductive core that extends in a direction substantially parallel to the top or bottom surface of the electronic package.

While planar magnetic devices are illustrated in FIGS. 7A and 7B, it is to be appreciated that magnetic devices may also include vertically oriented devices. In a vertically oriented device, the conductive core may extend in a direction that is substantially orthogonal to a top or bottom surface of the electronic package.

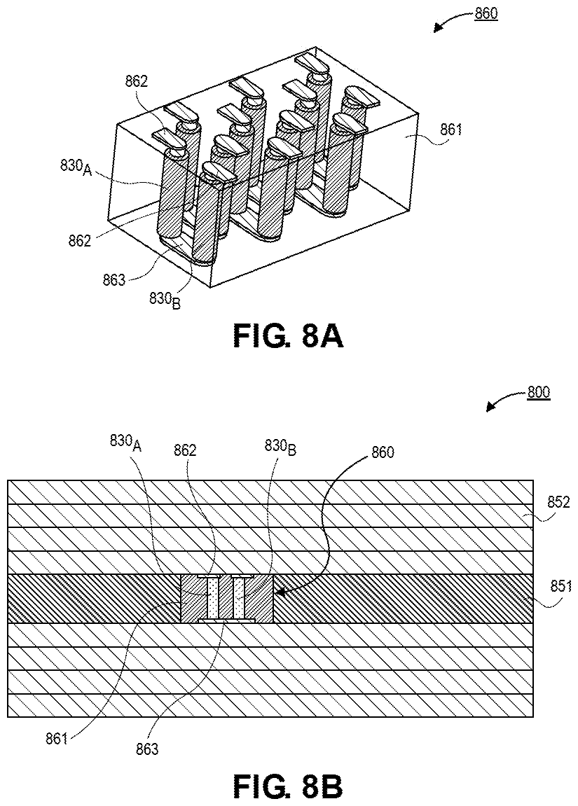

Referring now to FIG. 8A, a perspective view illustration of an inductor module 860 with vertically oriented interconnects 830 is shown, in accordance with an embodiment. In an embodiment, the plurality of interconnects 830 may be manufactured as a pin grid array (PGA) and molded together with a mold layer 861. Pads 862 may be disposed over first ends of the interconnects 830, and a linking trace 863 may electrically couple together neighboring interconnects 830A and 830B in order to form a vertically oriented loop.

In an embodiment, the interconnects 830 may be substantially similar to one or more of the interconnects described above. For example, the interconnects 830 may comprise a conductive core that is surrounded by a magnetic sheet. The magnetic sheet may comprise one or more magnetic layers and one or more insulating layers. In an embodiment, the magnetic layers may be strained magnetic layers. As such, a microstructure of the magnetic layers may have grains substantially oriented in a single direction. In an embodiment, the interconnects 830 may be formed with a winding process (e.g., similar to FIG. 3A) or with a rolling process (e.g., similar to FIG. 4).

Referring now to FIG. 8B, a cross-sectional illustration of an electronic package 800 is shown, in accordance with an embodiment. In an embodiment, the electronic package 800 may comprise a core 851 with a plurality of buildup layers 852 provided above and below the core 851. In an embodiment, an inductor module 860 may be embedded in the core 851. For example, an opening through the core 851 may be provided, and the inductor module 860 is placed in the opening. The buildup layers (including conductive routing (not shown)) may then be formed over the core 851 and the inductor module 860. In other embodiments, the electronic package 800 may be a coreless package substrate. In such an embodiment, the inductor module 860 may be embedded in one or more of the buildup layers 852.

In FIGS. 8A and 8B the interconnects 830 are shown as being embedded in a mold layer 861 prior to being integrated into the electronic package. However, it is to be appreciated that interconnects 830 may be directly integrated into the electronic package 800 in some embodiments. For example, via openings through the core 851 may be formed, and individual interconnects 830 may be inserted into the via openings. That is, in some embodiments, the interconnect 830 may directly contact the buildup layers 852 and/or the core 851.

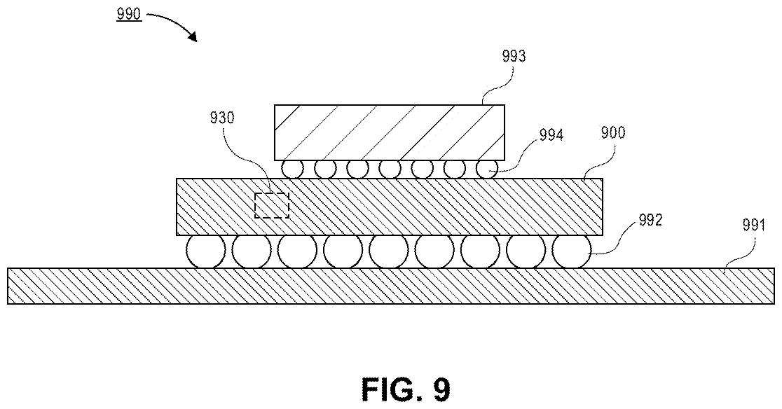

Referring now to FIG. 9, a cross-sectional illustration of an electronic system 990 is shown, in accordance with an embodiment. The electronic system 990 may comprise a board 991. The board 991 may be a printed circuit board (PCB), a motherboard, or the like. In an embodiment, an electronic package 900 is coupled to the board 991 by interconnects 992. The interconnects 992 may include any interconnect architecture, such as solder balls, sockets, or the like.

In an embodiment, the electronic package 900 may be substantially similar to any of the electronic packages described above. Particularly, the electronic package 900 may comprise one or more magnetic interconnects 930. The magnetic interconnects may comprise a conductive core with a magnetic sheet surrounding the conductive core. For example, the magnetic sheet may comprise a strained magnetic layer with a microstructure comprising grains that are substantially aligned in a single direction.

In an embodiment, a die 993 may be coupled to the electronic package 900 by interconnects 994. The interconnects 994 may be any first level interconnect (FLI) architecture. In an embodiment, one or more VR circuits may be provided on the die 993. The VR circuits may be electrically coupled to the one or more magnetic interconnects 930 in the electronic package 900.

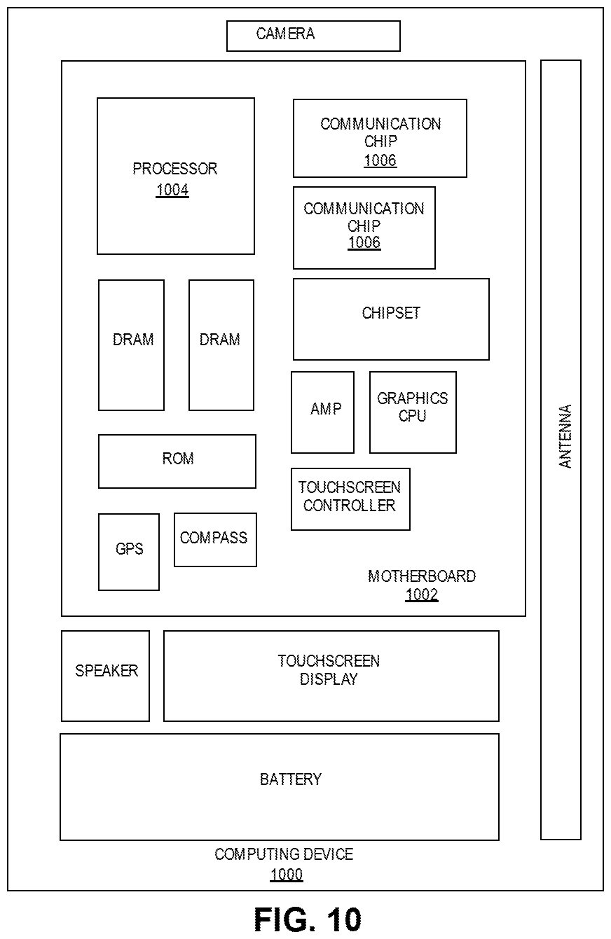

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor may be coupled to an electronic package that comprises a magnetic interconnect with a conductive core and a magnetic sheet with a strained magnetic layer, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip may be coupled to an electronic package that comprises a magnetic interconnect with a conductive core and a magnetic sheet with a strained magnetic layer, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an interconnect, comprising: a core, wherein the core has a thickness and a length between a first end and a second end, and wherein the core is conductive; and a magnetic sheet surrounding the core, wherein the magnetic sheet comprises is a magnetic layer with a microstructure that comprises grains that are substantially aligned in a single direction.

Example 2: the interconnect of Example 1, wherein the single direction is transverse to a length direction between the first end and the second end of the core.

Example 3: the interconnect of Example 2, wherein the single direction is substantially orthogonal to the length direction of the core.

Example 4: the interconnect of Examples 1-3, wherein the magnetic sheet has a sheet length, and wherein the sheet length is substantially equal to the length between the first end and the second end.

Example 5: the interconnect of Examples 1-3, wherein the magnetic sheet has a sheet length, and wherein the sheet length is smaller than the length between the first end and the second end.

Example 6: the interconnect of Example 5, wherein the magnetic sheet is wrapped around the core a plurality of times, wherein the magnetic sheet starts at the first end and terminates at the second end.

Example 7: the interconnect of Example 6, wherein the magnetic sheet is wrapped at an angle relative to a length direction of the core, and wherein the magnetic sheet overlaps a portion of itself with each successive wrap around the core.

Example 8: the interconnect of Examples 1-6, wherein the magnetic sheet further comprises: a first layer between the core and the magnetic layer, wherein the first layer is an insulator.

Example 9: the interconnect of Example 8, wherein the magnetic sheet further comprises: a second layer surrounding the magnetic layer, wherein the second layer is an insulator.

Example 10: the interconnect of Examples 1-9, further comprising: a second core surrounded by the magnetic sheet, wherein the second core is conductive.

Example 11: the interconnect of Example 10, wherein the second core is electrically isolated from the core by an insulating layer.

Example 12: the interconnect of Examples 1-11, wherein the interconnect is embedded in a mold layer.

Example 13: the interconnect of Example 12, wherein the mold layer is embedded in a package substrate core, and wherein the interconnect is oriented with the first end facing towards a top surface of the package substrate core and the second end facing towards a bottom surface of the package substrate core.

Example 14: the interconnect of Examples 1-11, wherein the interconnect is one interconnect of a plurality of interconnects bundled together and connected to a socket.

Example 15: the interconnect of Examples 1-11, wherein the interconnect is embedded in one or more buildup layers of a package substrate.

Example 16: the interconnect of Example 15, wherein a length direction between the first end and the second end is substantially parallel to a top surface of the buildup layer.

Example 17: an electronic package, comprising: a substrate core; a plurality of buildup layers above and below the substrate core; and an inductor embedded in the electronic package, wherein the inductor comprises an interconnect comprising: a wire, wherein the wire has a first end and a second end; and a magnetic sheet surrounding the wire, wherein the magnetic sheet comprises a magnetic layer, and wherein a microstructure of the magnetic layer has grains substantially aligned in a single direction.

Example 18: the electronic package of Example 17, wherein the inductor is embedded in the plurality of buildup layers.

Example 19: the electronic package of Example 18, wherein a length direction between the first end and the second end is substantially parallel to a topmost surface of the plurality of buildup layers.

Example 20: the electronic package of Examples 17-19, wherein the inductor is embedded in the substrate core.

Example 21: the electronic package of Example 20, wherein the inductor further comprises a second interconnect, wherein the second interconnect comprises: a second wire, wherein the second wire has a third end and a fourth end; and a second magnetic sheet surrounding the second wire, wherein the second magnetic sheet comprises a second magnetic layer, and wherein a microstructure of the second magnetic layer has grains substantially aligned in a single direction.

Example 22: the electronic package of Example 21, wherein the second end of the wire and the third end of the second wire are electrically coupled together by a trace.

Example 23: the electronic package of Example 21, wherein the inductor is embedded in a mold layer.

Example 24: an electronic system, comprising: a board; an electronic package electrically coupled to the board, wherein the electronic package comprises and interconnect embedded in the electronic package, wherein the interconnect comprises: a wire, wherein the wire is conductive; a first layer around the wire, wherein the first layer is insulative; a second layer over the first layer, wherein the second layer is magnetic; and a third layer around the second layer, wherein the second layer is insulative; and a die electrically coupled to the electronic package.

Example 25: the electronic system of Example 24, wherein the second layer comprises a microstructure with grains that are substantially aligned in a single direction.

What is claimed is:

1. An interconnect, comprising:
a core, wherein the core has a thickness and a length between a first end and a second end, and wherein the core is conductive; and
a magnetic sheet surrounding the core, wherein the magnetic sheet comprises is a magnetic layer with a microstructure that comprises grains that are substantially aligned in a single direction.

2. The interconnect of claim 1, wherein the single direction is transverse to a length direction between the first end and the second end of the core.

3. The interconnect of claim 2, wherein the single direction is substantially orthogonal to the length direction of the core.

4. The interconnect of claim 1, wherein the magnetic sheet has a sheet length, and wherein the sheet length is substantially equal to the length between the first end and the second end.

5. The interconnect of claim 1, wherein the magnetic sheet has a sheet length, and wherein the sheet length is smaller than the length between the first end and the second end.

6. The interconnect of claim 5, wherein the magnetic sheet is wrapped around the core a plurality of times, wherein the magnetic sheet starts at the first end and terminates at the second end.

7. The interconnect of claim 6, wherein the magnetic sheet is wrapped at an angle relative to a length direction of the core, and wherein the magnetic sheet overlaps a portion of itself with each successive wrap around the core.

8. The interconnect of claim 1, wherein the magnetic sheet further comprises:
a first layer between the core and the magnetic layer, wherein the first layer is an insulator.

9. The interconnect of claim 8, wherein the magnetic sheet further comprises:
a second layer surrounding the magnetic layer, wherein the second layer is an insulator.

10. The interconnect of claim 1, further comprising:
a second core surrounded by the magnetic sheet, wherein the second core is conductive.

11. The interconnect of claim 10, wherein the second core is electrically isolated from the core by an insulating layer.

12. The interconnect of claim 1, wherein the interconnect is embedded in a mold layer.

13. The interconnect of claim 12, wherein the mold layer is embedded in a package substrate core, and wherein the interconnect is oriented with the first end facing towards a top surface of the package substrate core and the second end facing towards a bottom surface of the package substrate core.

14. The interconnect of claim 1, wherein the interconnect is one interconnect of a plurality of interconnects bundled together and connected to a socket.

15. The interconnect of claim 1, wherein the interconnect is embedded in one or more buildup layers of a package substrate.

16. The interconnect of claim 15, wherein a length direction between the first end and the second end is substantially parallel to a top surface of the buildup layer.

17. An electronic package, comprising:
a substrate core;
a plurality of buildup layers above and below the substrate core; and
an inductor embedded in the electronic package, wherein the inductor comprises an interconnect comprising:
a wire, wherein the wire has a first end and a second end; and
a magnetic sheet surrounding the wire, wherein the magnetic sheet comprises a magnetic layer, and wherein a microstructure of the magnetic layer has grains substantially aligned in a single direction.

18. The electronic package of claim 17, wherein the inductor is embedded in the plurality of buildup layers.

19. The electronic package of claim 18, wherein a length direction between the first end and the second end is substantially parallel to a topmost surface of the plurality of buildup layers.

20. The electronic package of claim 17, wherein the inductor is embedded in the substrate core.

21. The electronic package of claim 20, wherein the inductor further comprises a second interconnect, wherein the second interconnect comprises:
a second wire, wherein the second wire has a third end and a fourth end; and
a second magnetic sheet surrounding the second wire, wherein the second magnetic sheet comprises a second magnetic layer, and wherein a microstructure of the second magnetic layer has grains substantially aligned in a single direction.

22. The electronic package of claim 21, wherein the second end of the wire and the third end of the second wire are electrically coupled together by a trace.

23. The electronic package of claim 21, wherein the inductor is embedded in a mold layer.

24. An electronic system, comprising:
a board;
an electronic package electrically coupled to the board, wherein the electronic package comprises and interconnect embedded in the electronic package, wherein the interconnect comprises:
a wire, wherein the wire is conductive;
a first layer around the wire, wherein the first layer is insulative;
a second layer over the first layer, wherein the second layer is magnetic; and
a third layer around the second layer, wherein the second layer is insulative; and
a die electrically coupled to the electronic package.

25. The electronic system of claim 24, wherein the second layer comprises a microstructure with grains that are substantially aligned in a single direction.
